(19) United States
(12) Patent Application Publication
(10) Pub. No.: US 2025/0189901 A1
(43) Pub. Date: Jun. 12, 2025

(54) CRITICAL DIMENSION UNIFORMITY TUNING BASED ON MASK DESIGN FEATURE DENSITY

(71) Applicant: Tokyo Electron Limited, Tokyo (JP)

(72) Inventors: Daniel FULFORD, Albany, NY (US); David POWER, Albany, NY (US); David CONKLIN, Saratoga Springs, NY (US)

(73) Assignee: Tokyo Electron Limited, Tokyo (JP)

(21) Appl. No.: 18/618,278

(22) Filed: Mar. 27, 2024

Related U.S. Application Data
(60) Provisional application No. 63/607,648, filed on Dec. 8, 2023.

(51) Int. Cl. G03F 7/00; G03F 7/42

(52) U.S. Cl. CPC G03F 7/70625; G03F 7/427; G03F 7/70383; G03F 7/70633

(57) ABSTRACT

A method of processing a substrate, including generating a mask density map based on a photomask, the mask density map spatially mapping transparent regions of the photomask and blocking regions of the photomask that block radiation at a predetermined wavelength; generating a flare map based on the mask density map, the flare map spatially indicating a projected amount of received radiation in excess of a desired amount of radiation at each coordinate location on the photomask; and generating a critical dimension modification map based on the flare map, the critical dimension modification map including a modification energy dosage for each coordinate location on the photomask.

### CROSS-REFERENCE TO RELATED APPLICATIONS

The present application claims priority to U.S. Provisional Application No. 63/607,648, filed Dec. 8, 2023, which is incorporated herein by reference in its entirety for all purposes.

### TECHNICAL FIELD

This disclosure relates generally to methods of microfabrication, and more specifically to photolithography.

### BACKGROUND

The background description provided herein is for the purpose of generally presenting the context of the disclosure. Work of the presently named inventors, to the extent the work is described in this background section, as well as aspects of the description that may not otherwise qualify as prior art at the time of filing, are neither expressly nor impliedly admitted as prior art against the present disclosure.

Semiconductor fabrication involves multiple varied steps and processes. One typical fabrication process is known as photolithography (also called microlithography). Photolithography uses radiation, such as ultraviolet or visible light, to generate fine patterns in a semiconductor device design. Many types of semiconductor devices, such as diodes, transistors, and integrated circuits, can be constructed using semiconductor fabrication techniques including photolithography, etching, film deposition, surface cleaning, metallization, and so forth.

Exposure systems (also called exposure tools) are used to implement photolithographic techniques. An exposure system typically includes an illumination system, a reticle (also called a photomask) or spatial light modulator (SLM) for creating a circuit pattern, a projection system, and a wafer alignment stage for aligning a photosensitive resist-covered semiconductor wafer. The illumination system illuminates a region of the reticle or SLM with a (preferably) rectangular slot illumination field. The projection system projects an image of the illuminated region of the reticle pattern onto the wafer. For accurate projection, it is important to expose a pattern of light on a wafer that is relatively flat or planar, preferably having less than 10 microns of height deviation.

It can be desired to expose a single wafer to a pattern of light that includes varying exposure doses of radiation in order to achieve features of different sizes.

### SUMMARY

In one embodiment, the present disclosure relates to a method of processing a substrate, the method comprising generating a mask density map based on a photomask, the mask density map spatially mapping transparent regions of the photomask and blocking regions of the photomask that block radiation at a predetermined wavelength; generating a flare map based on the mask density map, the flare map spatially indicating a projected amount of received radiation in excess of a desired amount of radiation at each coordinate location on the photomask; generating a critical dimension modification map based on the flare map, the critical dimension modification map including a modification energy dosage for each coordinate location on the photomask; coating a first surface of the substrate with a photosensitive resist; exposing the first surface of the substrate to a first pattern of radiation at the predetermined wavelength when the photomask is provided between the first surface of the substrate and a source of the radiation; and exposing the first surface of the substrate to a second pattern of radiation at the predetermined wavelength, the second pattern being based on modification energy dosages of the critical dimension modification map.

In one embodiment, the present disclosure relates to a method of processing a substrate, the method comprising generating a mask density map based on a photomask, the mask density map spatially mapping transparent regions of the photomask and blocking regions of the photomask that block radiation at a predetermined wavelength; generating a flare map based on the mask density map, the flare map spatially indicating a projected amount of electromagnetic radiation in excess of a desired amount of electromagnetic radiation received at each coordinate location on the photomask; generating a critical dimension modification map based on the flare map, the critical dimension modification map including a modification energy dosage for each coordinate location on the photomask; coating a first surface of the substrate with a photosensitive resist; exposing the first surface of the substrate to a first pattern of radiation at the predetermined wavelength when the photomask is provided between the first surface of the substrate and a source of the radiation; exposing the first surface of the substrate to a second pattern of radiation at the predetermined wavelength, the second pattern being based on modification energy dosages of the critical dimension modification map; and removing portions of the photosensitive resist after exposing the first surface of the substrate to the first pattern of radiation and exposing the first surface of the substrate to the second pattern of radiation.

Note that this summary section does not specify every embodiment and/or incrementally novel aspect of the present disclosure or claimed invention. Instead, this summary only provides a preliminary discussion of different embodiments and corresponding points of novelty. For additional details and/or possible perspectives of the invention and embodiments, the reader is directed to the Detailed Description section and corresponding figures of the present disclosure as further discussed below.

### BRIEF DESCRIPTION OF THE DRAWINGS

A more complete appreciation of the invention and many of the attendant advantages thereof will be readily obtained as the same becomes better understood by reference to the following detailed description when considered in connection with the accompanying drawings, wherein:

FIG. 1 is an illustration of scattering in a lens, according to one embodiment of the present disclosure;

FIG. 2 is a graph of radiation intensity, according to one embodiment of the present disclosure;

FIG. 3 is a cross-sectional view of an example direct write projection system, according to one embodiment of the present disclosure;

FIG. 4 is a schematic view of a mask-based photolithographic exposure system, according to one embodiment of the present disclosure;

FIG. 5 is a cross-sectional schematic view of an example dispense system, according to one embodiment of the present disclosure;

FIG. 6 is a method of processing a substrate, according to one embodiment of the present disclosure;

FIG. 7 is a composite photomask, according to one embodiment of the present disclosure;

FIG. 8 is an illustration of photomask features, according to one embodiment of the present disclosure;

FIG. 9 is a map of energy received at a photomask, according to one embodiment of the present disclosure;

FIG. 10 is a mask density map, according to one embodiment of the present disclosure;

FIG. 11 is a statistical analysis of a mask density map, according to one embodiment of the present disclosure;

FIG. 12 is a comparison between a map of received energy and critical dimensions, according to one embodiment of the present disclosure;

FIG. 13A is a map of critical dimensions, according to one embodiment of the present disclosure; and

FIG. 13B is an exposure pattern, according to one embodiment of the present disclosure.

### DETAILED DESCRIPTION OF THE PREFERRED EMBODIMENTS

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed. Further, spatially relative terms, such as “top,” “bottom,” “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The order of discussion of the different steps as described herein has been presented for clarity's sake. In general, these steps can be performed in any suitable order. Additionally, although each of the different features, techniques, configurations, etc. herein may be discussed in different places of this disclosure, it is intended that each of the concepts can be executed independently of each other or in combination with each other. Accordingly, the present invention can be embodied and viewed in many different ways.

The present disclosure is related to techniques for selective exposure of a wafer to actinic radiation for development of photosensitive resist (photoresist) on the wafer. Specifically, the systems and methods described herein can be used to control and adjust exposure of locations within a wafer to a radiation source in order to provide resolution enhancement and improve the precision of feature development and wafer bow correction. A location can be a point location, area, or region of the wafer. A region, as used herein, can be within a single die or can refer to an individual die or frame on a wafer.

Critical dimension uniformity (CDU) control is important in fabrication of semiconductor devices. Features and structures on a substrate should be fabricated with uniform critical dimensions (CDs) to ensure high chip yield and performance. CD variation can occur during photolithography when a wafer is exposed to more energy (e.g., radiation) than is expected during the fabrication process. The extra energy can be a result of ambient light or radiation sources (e.g., laser beams) used in fabrication. The sum of extra energy can be referred to as flare, and flare can be measured in units of energy. Flare can vary across a single substrate or wafer. For example, different locations of a wafer can be exposed to different amounts of radiation during fabrication as a result of the feature pattern of the wafer. Locations that are exposed to more radiation in order to develop certain features may also be exposed to more flare than locations that are exposed to comparatively less radiation. Additional energy can shrink the process window for successful exposure, which can lead to defects and failures, including features that are not printed. Small amounts of flare (e.g., less than 1%) can cause CDs to vary on the order of nanometers.

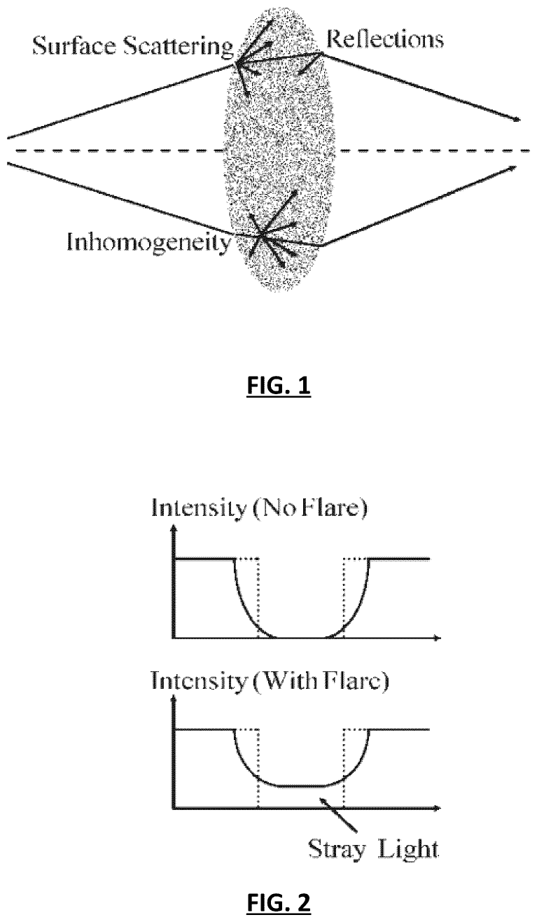

FIG. 1 is an illustration of sources of flare in photolithography. Reflections at the interfaces of a lens and other imperfections, including particles, surface roughness, and inhomogeneity of the glass, can cause light to scatter. The scattered light can reach the substrate as flare. The intensity of exposure of the substrate can be seen in the graph of FIG. 2. When there is no flare in the system, the intensity of radiation can be gradually reduced to zero as needed. When there is flare in the system, the intensity of radiation may remain non-zero, resulting in unwanted irradiation of the substrate.

Photomask exposure of a substrate can be a primary source of flare. In one embodiment, the present disclosure is directed to determining an expected amount of flare resulting from a first exposure process and correcting for the flare via a second exposure process. The expected amount of flare resulting from a first exposure process can be determined based on the photomask used for the exposure. The second exposure process can correct for the flare using a second exposure pattern, which can be determined based on the photomask. The combination of the first exposure process and the second exposure process can be used to fabricate a substrate having accurate and uniform feature CDs. The second exposure process (also referred to herein as a correction exposure) can follow or can precede the first exposure process. The designation of “first” and “second” herein are not limitations on the execution order of the processes.

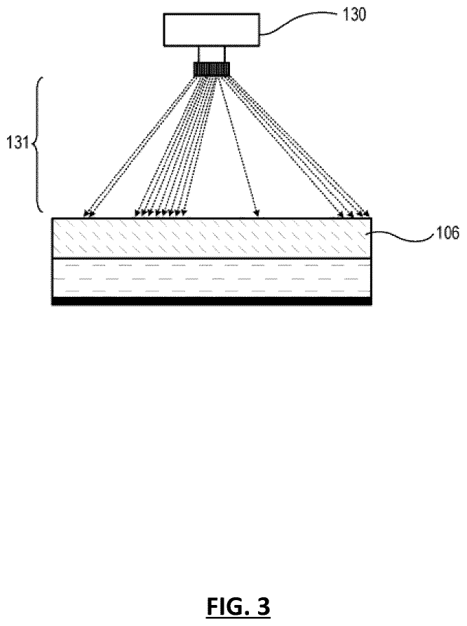

In one embodiment, the correction exposure can be provided via a direct write system or similar maskless process. FIG. 3 illustrates an example cross-sectional drawing of a direct write system 130. Pattern 131 (e.g., a correction exposure pattern) can be projected onto photoresist film 106. The pattern 131 can vary in amount of radiation per coordinate location based on a composite critical dimension signature and/or an expected amount of flare. The intensity of projection at any point location can be adjustable from zero actinic radiation to full exposure or any gradation of light intensity in between. Variation of light intensity can be controlled by a micro-mirror array, such as a digital light processing (DLP) chip. An entire substrate or a large portion of a substrate can be exposed at one time. In one embodiment, a laser galvanometer can be used to move a laser beam stepwise across a substrate. The dwell time of the laser beam at each location can vary the amount of radiation that is delivered.

In one embodiment, the direct write system can provide a relatively small proportion (e.g., 0.1% to 10%, 1% to 3%) of radiation that is required to pattern the features in the substrate. The first exposure process can provide the remaining amount of radiation. In one example, the first exposure dose can be lowered by a corrective amount (e.g., the correction exposure dose) to prevent overexposure of the substrate as a result of flare during the first exposure. The correction exposure can then be used to achieve desired CD resolution and uniformity. The reduction in the first exposure dose can pull regions of overexposure into the area of the process window. The methods described herein can reduce the total exposure energy so that the energy falls within a smaller processing window, resulting in more accurately printed features. The exposure energy of the photoresist will reach a threshold activation energy without exceeding the process window.

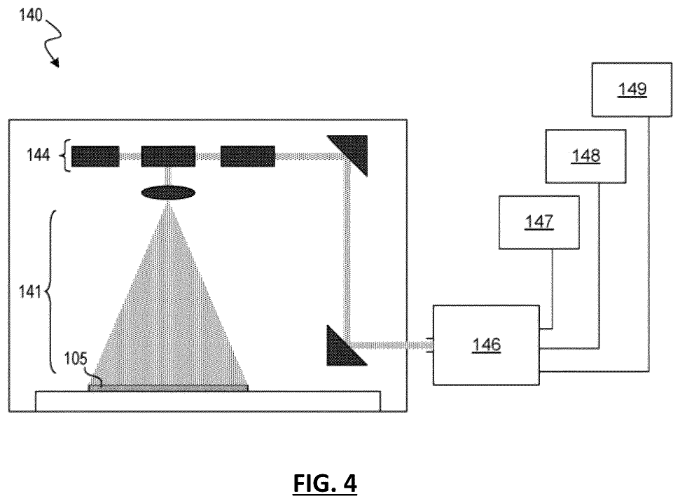

In one embodiment, the first exposure can be provided via mask-based photolithographic exposure. In one embodiment, the second exposure can also be provided via a mask-based photolithographic exposure. FIG. 4 is an illustration of an exposure system 140 according to one embodiment of the present disclosure. The exposure system 140 can be a mask-based photolithographic exposure system such as a stepper or scanner. The exposure system 140 can have a higher spatial resolution as compared to the direct write system 130. Exposure system 140 can include optics 144 receiving light from light source 146 to project pattern 141, which can be a mask-based pattern. Input 147, input 148, and input 149 can include various gases, such as ArF, N₂, and helium for use by a given laser light source. Such exposures systems are conventionally known and so only a simplified description is provided here. Conventional mask-based systems commonly use 193 nm wavelength light, which can print feature sizes down to about 50 nm. Not all direct write systems can achieve that resolution or achieve that resolution efficiently. Resolutions of direct write systems can be limited to sizes of micro mirrors or beam sizes. Techniques herein, however, can combine both exposure systems to provide a combination maskless dynamic exposure and a mask-based pattern exposure to correct repeated patterns without measuring every substrate.

In embodiments in which multiple wavelength exposures occur, photoresist films can be formed that are sensitive to a first wavelength for the direct write exposure and yet sensitive to a second wavelength for a remaining or full mask-based exposure. Moreover, a type of agent sensitive to the radiation can optionally be selected to generate either an acid or a base on light exposure and/or be thermally sensitive so that the heat of white light or infrared, for example, can activate. Any combinations of actinic radiation can be used between the two exposure systems. Example wavelengths for combination exposures include 172 nm, 193 nm, 248 nm, 256 nm 365 nm, white light, and infrared light.

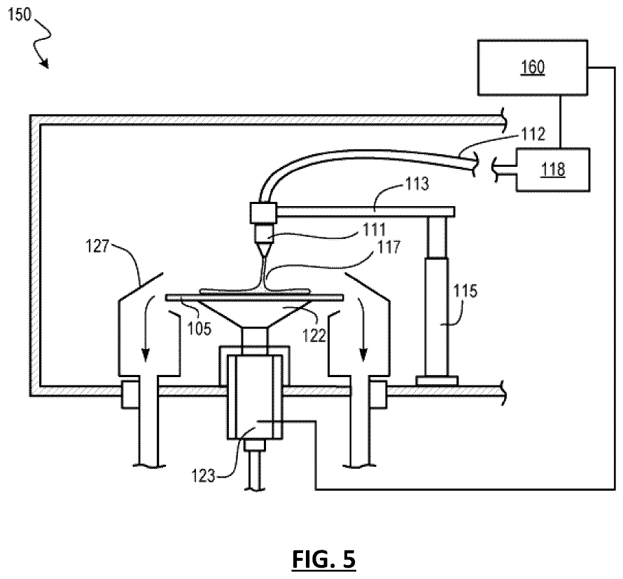

FIG. 5 is an illustration of a coater-developer system 150 for exposing, developing, etching, and stripping substrates. A substrate can be coated with a photoresist film using coater-developer module 150 as a system for dispensing liquid on a substrate 105. Substrate holder 122 is configured to hold substrate 105 and rotate substrate 105 about an axis. Motor 123 can be used to rotate the substrate holder 122 at a selectable rotational velocity. A dispense unit 118 is configured to dispense liquid on a working surface of the substrate 105 while the substrate 105 is being rotated by the substrate holder 122. Dispense unit 118 can be positioned directly over a substrate holder, or can be positioned at another location. If positioned away from the substrate holder, than a conduit 112 can be used to deliver fluid to the substrate. The fluid can exit through nozzle 111. FIG. 5 illustrates liquid 117 being dispensed onto a working surface of substrate 105. Collection system 127 can then be used to catch or collect excess liquid 117 that spins off substrate 105 during a given dispense operation. Dispense components can include nozzle arm 113 as well as support member 115, which can be used to move a position of nozzle 111 across the substrate 105, or to be moved away from the substrate holder 122 to a resting location, such as for rest upon completion of dispense operations. The dispense unit 118 can alternatively be embodied as a nozzle itself. Such a nozzle can have one or more valves in communication with system controller 160. The dispense unit 118 can have various embodiments configured to control dispense of a selectable volume of fluid on a substrate, and to dispense combination of fluids.

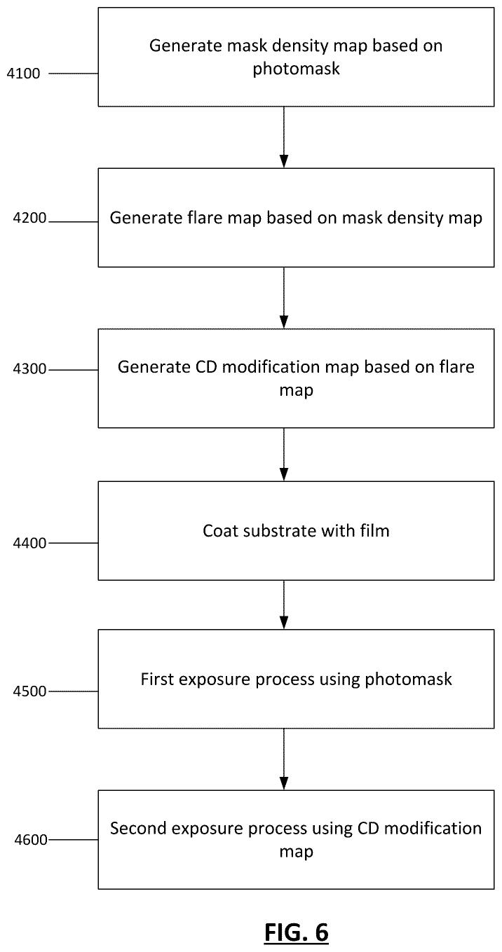

FIG. 6 is a method of determining a correction pattern for a substrate. The correction pattern can be generated based on the original photomask used for photolithography. In step 4100, a mask density map is generated based on the photomask. The mask density map can be a mapping of open regions of the photomask. The mask density map can spatially map locations where the photomask is transparent (open) to a given wavelength or wavelengths of electromagnetic radiation (e.g., actinic radiation) and locations where the photomask blocks a given wavelength or wavelengths of electromagnetic radiation (e.g., actinic radiation). In one embodiment, the density of a feature can be a percentage of total mask area that the feature occupies. In one example, the density of an open region can be determined in millijoule per square centimeters (mJ/cm²). In one embodiment, the density of an open region can be a percentage of total open area, and the density of an opaque region can be a percentage of total opaque area. For example, density can be a percentage of the non-chrome area, wherein chrome is a blocking material that separates open features. In one example, the locations can be defined according to a grid or a coordinate system. In one example, the locations can be pixel locations. The locations can correspond to features of the photomask. For example, features that are developed by removal of photoresist are open to electromagnetic radiation. The photomask can include features such as closely spaced lines, widely spaced lines, and shapes of various geometries, sizes, and separations on the substrate.

In step 4200, a flare map is generated based on the mask density map. The flare map can indicate an amount of additional electromagnetic radiation (flare) that is received at locations across the substrate based on the transparent and opaque locations in the mask density map. The flare can be determined as a projection or prediction of the additional electromagnetic radiation. In one embodiment, the flare map can be generated based on a simulation of electromagnetic radiation (e.g., light from the light source 146 of a mask-based photolithography exposure system) incident on the mask density map. In one embodiment, the predicted flare can be directly proportional to the density of open locations on the mask density map. For example, more energy will pass through the mask at open locations. A concentrated region of open locations on the mask can result in increased or prolonged radiation being directed toward the concentrated region, resulting in increased flare. In one embodiment, the occurrence of flare can depend on the geometry and gradients of features on the photomask.

In step 4300, a CD modification map is generated based on the flare map. The CD modification (or correction) map can include a correction dosage of energy to be applied at each location (e.g., a pixel, a coordinate location) on the substrate. The correction dosage can be calculated based on the flare at each location, which is simulated in the flare map of step 4200. For example, the correction dosage can be calculated based on a difference between the total amount of energy a location receives during the first exposure process and a desired amount of energy. The total amount of energy received during the first exposure process includes the simulated flare. The CD modification map can indicate the correction exposure pattern that is used in the second exposure. In one example, the CD modification map can be a digital file. The CD modification map can be provided to a direct write system, and the direct write system can apply the second exposure pattern based on the CD modification map.

In step 4400, the substrate can be coated with the radiation-sensitive patterning film in preparation for exposure to actinic radiation. The patterning film can be the photoresist film 106 of FIG. 3. In step 4500, the first exposure process can be executed. The first exposure process can be a mask-based photolithography exposure using the photomask, as described with reference to FIG. 4. The structures of the photomask can thereby be patterned onto the substrate to generate a circuit design.

In step 4600, the second exposure process can be executed. The second exposure process can be a direct write process using a second pattern of actinic radiation, as described with reference to FIG. 3. The second pattern of actinic radiation can be based on the CD modification map generated in step 4300. In one embodiment, the direct write system can vary an intensity of light at coordinates across the substrate according to the correction dosages of the CD modification map. The second exposure process can correct for varying amounts of flare that are directed at the substrate during the first exposure process. The combination of the first exposure process and the second exposure process can result in features having the desired, uniform CDs.

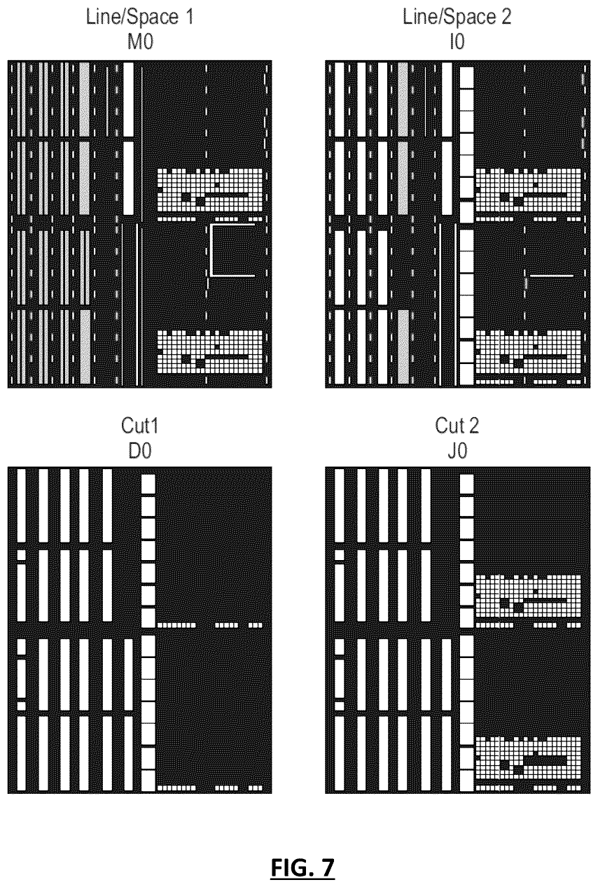

FIG. 7 is an illustration of a photomask according to one embodiment of the disclosure. The photomask is a composite photomask and includes four individual photomasks (M0, I0, D0, J0). The composite photomask can be used to pattern a substrate with multiple exposures. For example, the substrate can be exposed to the first pattern of radiation when the first photomask M0 is positioned between the substrate and the light source. The second photomask I0 can then be positioned between the substrate and the light source. and the substrate can be exposed to the first pattern of radiation. The first pattern of radiation can be repeated for each photomask of the composite photomask. Each photomask can have different open (transparent) regions corresponding to different features that are patterned on the substrate with each exposure. For example, each photomask and corresponding exposure can correspond to a certain patterning step, such as creating a line/space pattern or line cuts.

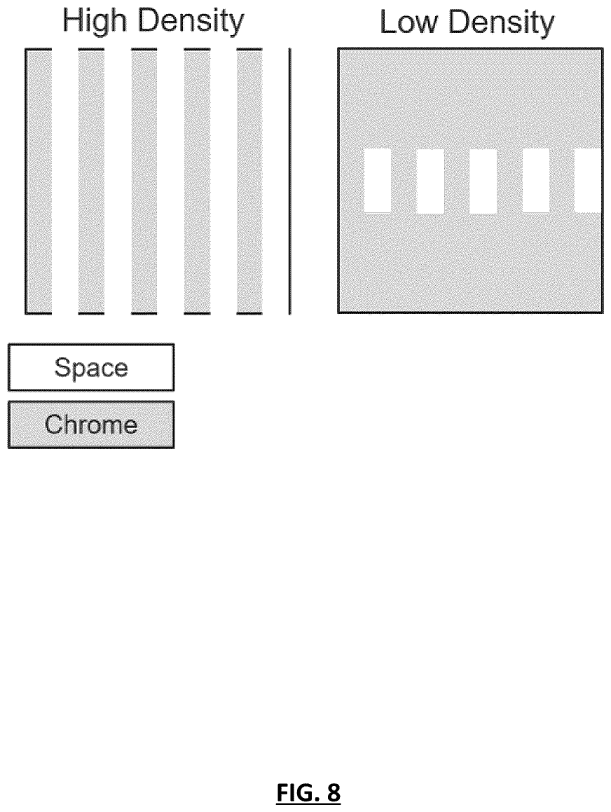

FIG. 8 is an illustration of photomask features according to one embodiment. A high-density region of the mask can be a region having larger (longer) open spaces. The open spaces can be separated by chrome, which can block radiation. A low-density region of the mask can be a region having smaller (shorter) open spaces. While the spacing between the open spaces in the high-density region and the low-density region is similar, the length of the open spaces in the high-density region results in greater energy and greater flare directed toward the high-density region. In one example, the substrate can receive a dose of approximately 50 mJ (millijoule). The amount of energy at locations of the wafer can be directly proportional to the density of open spaces (features) on the photomask.

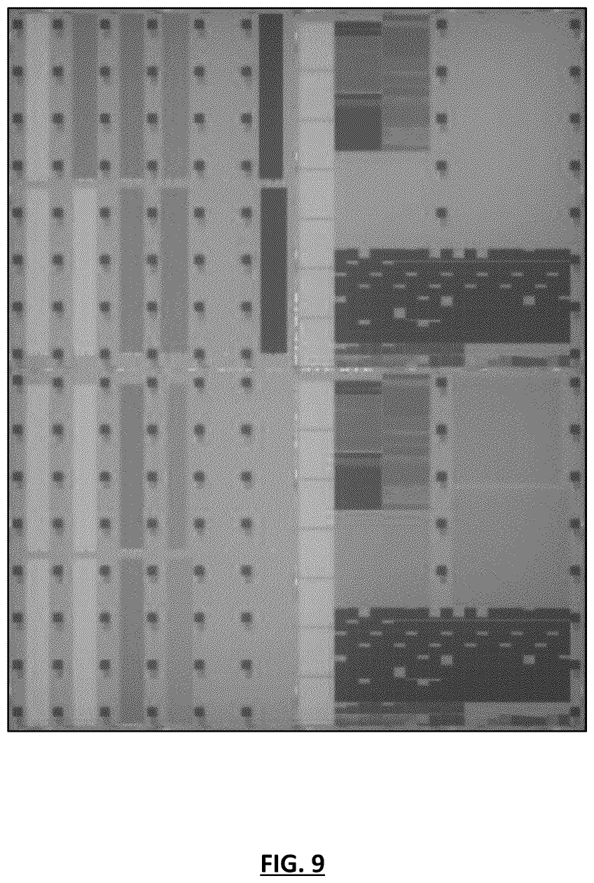

FIG. 9 is an example of energy received by a substrate as a result of the first photomask design (M0) of FIG. 7, according to one embodiment. The received energy can be greater at locations with high density of features, e.g., rows of features that are close together. The received energy can also be greater at locations where the same features or proximal features are repeatedly exposed by the photomask.

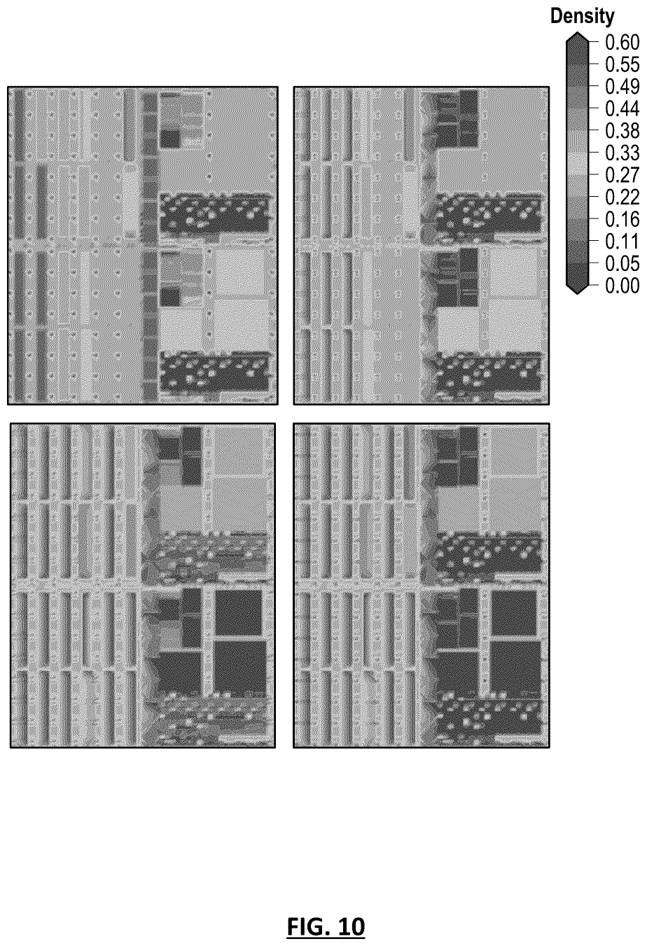

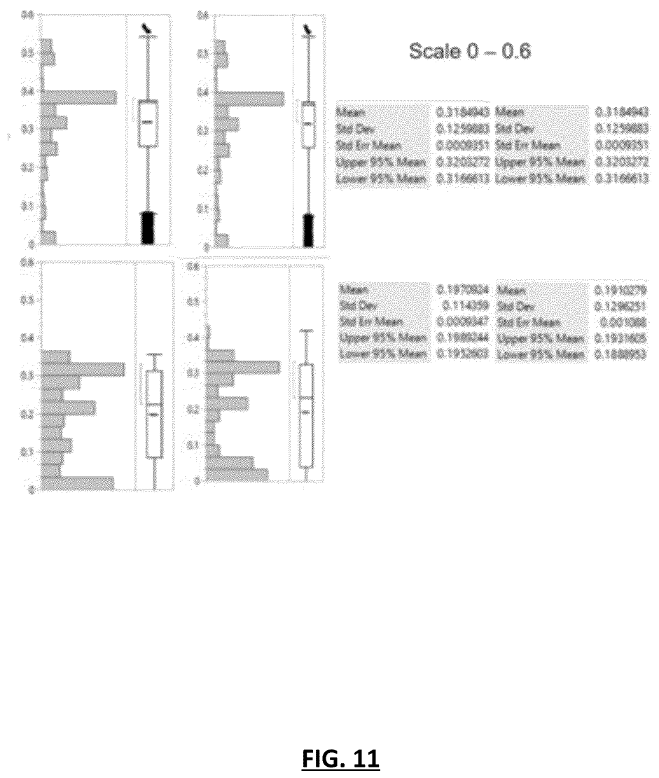

FIG. 10 is a mask density map of the composite photomask of FIG. 7. The density of features can vary within each photomask of the composite photomask. The density of features can also vary between each photomask. For example, the average density of open space in each of the top photomasks can be approximately 0.32 (32% of area), while the average density of each of the bottom row of photomasks can be approximately 0.19 (19% of area). Features can be patterned onto a substrate via multiple exposures. FIG. 11 includes histograms and statistical measures of the densities in the density map of FIG. 11. In one embodiment, the density maps for each of the photomasks in a composite photomask can be combined to generate a single (composite) density map. The composite density map can be used to determine the total amount of energy that will be received at each location of a substrate over multiple exposures via the composite photomask. In one embodiment, the flare map and the CD modification map as described herein can then be generated based on a composite density map.

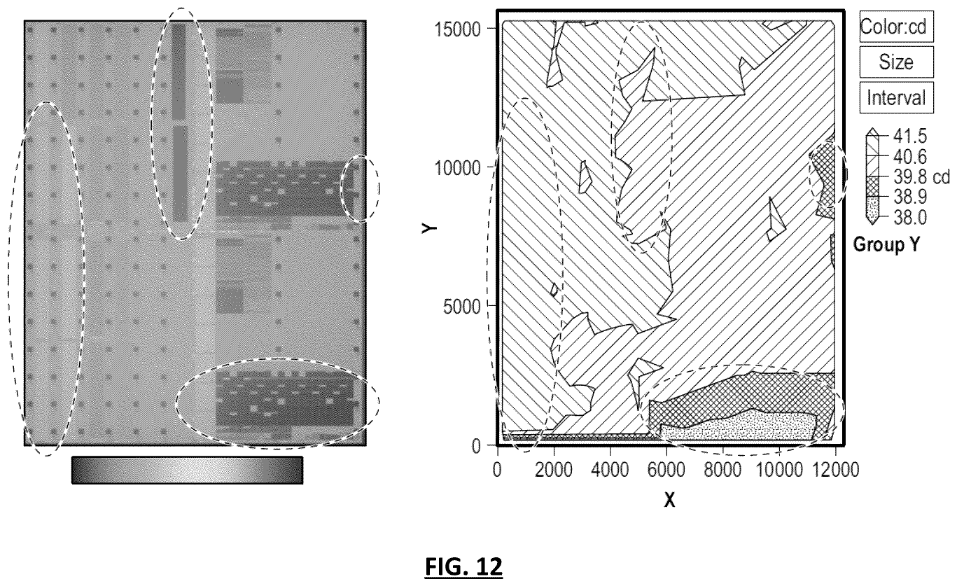

FIG. 12 is an illustration of the correlation between the energy received at locations on a photomask during the first exposure process and the critical dimensions of features on the substrate resulting from the exposure. The critical dimensions can be on the scale of nanometers (nm). The CDs of features can be measured in order to determine variability between the desired CD and the actual CD. The difference or error in CD can then be used to generate a CD correction signature (map), which can be applied in a second exposure process, e.g., a direct write process. The CD correction signature can include varying correction dosages that can be applied to locations of the substrate. In one embodiment, the CD variation at a location on the substrate can be correlated with the amount of energy received at that location during the first exposure process. The correction dosage that is applied to the location during the second exposure process is therefore also correlated with the amount of energy received during the first exposure process.

Metrology of critical dimensions, as in the process used to generate the CD correction signature of FIG. 12, can be time-consuming and can require additional measurement equipment. In one embodiment, the methods provided herein can improve fabrication throughput by allowing for the development of an accurate CD correction map without metrology of developed features. The CD correction map can be generated based on the original photomask and does not require data that is collected from the patterned substrate itself. In one embodiment, the methods described herein can be combined with measurement of CDs for increased accuracy for the CD correction map.

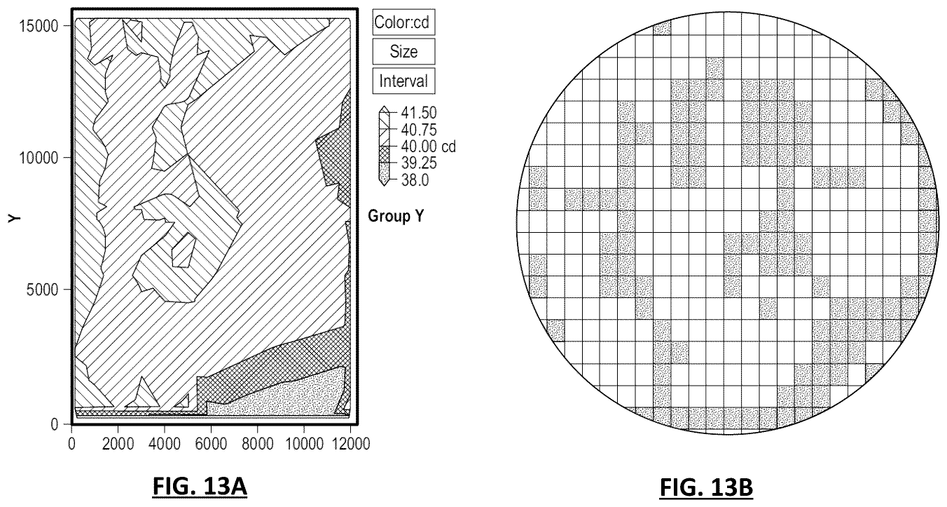

FIG. 13A is an example of critical dimensions of features (in nanometers) that are generated by the method of FIG. 6. The features can be corrected via a first exposure process and a second exposure process, the second exposure process being a direct write system based on a CD modification map. The second exposure process can be executed directly before or after the first exposure process. The CDs can be more accurate and uniform than features that are generated without a second exposure process. In this manner, the fabrication process can be streamlined while maintaining the accuracy of CD correction. FIG. 13B is an image of the correction dosages that are applied to a substrate.

In one embodiment, the second exposure process can be executed while selectively covering and exposing regions of the substrate. For example, different regions of a substrate (e.g., a wafer) can correspond to dies having different patterns. A single CD correction map can be generated for the wafer according to the method of FIG. 6. The CD correction map can include correction dosages corresponding to the different patterns on the wafer.

In one embodiment, the method for selectively isolating and exposing regions of a wafer can include applying a shield between the wafer and a radiation source during irradiation. In one embodiment, the shield can include one or more mechanical blades affixed over a wafer so that only a select region of the wafer is exposed to radiation (e.g., a laser beam). The one or more mechanical blades can refer to overlapping sheets or pieces of opaque material forming an aperture (opening) at the center. The mechanical blades can be similar in structure to the aperture blades of a lens. The one or more mechanical blades can be provided between the wafer and the laser beam source. The laser beam can irradiate a region of the wafer that is exposed through the at least one aperture of the one or more mechanical blades. The at least one aperture can be large enough that the laser beam can be stepped across the exposed region. As described previously, the exposed region can correspond to a wafer die.

The one or more mechanical blades can cover the remaining area of the wafer outside of the exposed region. In one embodiment, the one or more mechanical blades can be overlapping blades, and the amount of overlap of the blades can be adjusted to adjust the size of the aperture. For example, the position, orientation, or overlap of the one or more mechanical blades can be adjusted to change the size and/or shape of the aperture. Thus, the one or more mechanical blades can be used to set the size and/or shape of the exposed region that is visible through the aperture. In one embodiment, the one or more mechanical blades can be affixed above the wafer and closer to the wafer than to the laser beam source. The wafer can be moved relative to the one or more mechanical blades or vice versa in order to expose different regions through the aperture.

In this manner, the laser beam of the second exposure process can be applied to each die individually until all of the dies have been properly irradiated. In an embodiment, the exposure dose (e.g., exposure time) of the laser beam can be adjusted based on each die pattern. By exposing each die individually, the critical dimensions of features of each die can be accurately patterned without affecting surrounding dies.

It can be appreciated that the one or more mechanical blades are provided herein as a non-limiting example of a shielding structure that can cover a first region of a wafer while exposing a second region within an aperture. In one embodiment, a mask (e.g., photomask) can be applied over the wafer. The photomask can be an opaque mask including a pattern of apertures, the apertures being transparent regions or cutouts in the photomask. Radiation applied to the photomask can penetrate through the apertures while being blocked by the opaque regions. The pattern of the mask can be based on the layout of a wafer. The layout can refer to the number, size, spacing, and position of dies on a surface (e.g., the working surface) of the wafer. For example, the size of the apertures and the spacing between transparent regions can correspond to the size and spacing of dies on the wafer. A wafer can be positioned beneath the mask so that a die is exposed via each of the one or more apertures. In one embodiment, the mask can be provided between the wafer and the laser beam source and can be closer to the wafer than to the laser beam source. In one embodiment, the mask can include a single aperture to expose one die at a time in a similar manner to the one or more mechanical blades described herein. The mask can be displaced over the wafer (e.g., by a wafer stage) to expose die regions via the one or more apertures. The laser beam can be stepped across the one or more apertures in order to irradiate each exposed die.

In one embodiment, the mask can include a pattern of apertures to simultaneously expose a set of dies while covering remaining regions, including other dies, on the wafer. In one embodiment, the set of dies that are simultaneously exposed by the mask can be dies that are exposed to the same pattern or amount of radiation. In one embodiment, the set of dies that are simultaneously exposed by the mask can be dies that receive a correction dosage of radiation exposure.

Isolating sets of dies on a wafer using a mask can enable adjustment of exposure dose across a single wafer in order to achieve the desired feature CDs of each die. The CDs can be varied across the wafer as well as across each die with high precision. In an embodiment, the bow of the wafer at the location of each die can be measured and known. The exposure dose can be adjusted for each die in order to control or correct the bow at the die, resulting in a more uniform wafer. The mask can be applied to the wafer before or after photolithography mask application or exposure.

In the preceding description, specific details have been set forth, such as a particular geometry of a processing system and descriptions of various components and processes used therein. It should be understood, however, that techniques herein may be practiced in other embodiments that depart from these specific details, and that such details are for purposes of explanation and not limitation. Embodiments disclosed herein have been described with reference to the accompanying drawings. Similarly, for purposes of explanation, specific numbers, materials, and configurations have been set forth in order to provide a thorough understanding. Nevertheless, embodiments may be practiced without such specific details. Components having substantially the same functional constructions are denoted by like reference characters, and thus any redundant descriptions may be omitted.

Various techniques have been described as multiple discrete operations to assist in understanding the various embodiments. The order of description should not be construed as to imply that these operations are necessarily order dependent. Indeed, these operations need not be performed in the order of presentation. Operations described may be performed in a different order than the described embodiment. Various additional operations may be performed and/or described operations may be omitted in additional embodiments.

“Substrate” or “target substrate” as used herein generically refers to an object being processed in accordance with the invention. The substrate may include any material portion or structure of a device, particularly a semiconductor or other electronics device, and may, for example, be a base substrate structure, such as a semiconductor wafer, reticle, or a layer on or overlying a base substrate structure such as a thin film. Thus, substrate is not limited to any particular base structure, underlying layer or overlying layer, patterned or un-patterned, but rather, is contemplated to include any such layer or base structure, and any combination of layers and/or base structures. The description may reference particular types of substrates, but this is for illustrative purposes only.

The substrate can be any suitable substrate, such as a silicon (Si) substrate, a germanium (Ge) substrate, a silicon-germanium (SiGe) substrate, and/or a silicon-on-insulator (SOI) substrate. The substrate may include a semiconductor material, for example, a Group IV semiconductor, a Group III-V compound semiconductor, or a Group II-VI oxide semiconductor. The Group IV semiconductor may include Si, Ge, or SiGe. The substrate may be a bulk wafer or an epitaxial layer.

Those skilled in the art will also understand that there can be many variations made to the operations of the techniques explained above while still achieving the same objectives of the invention. Such variations are intended to be covered by the scope of this disclosure. As such, the foregoing descriptions of embodiments of the invention are not intended to be limiting. Rather, any limitations to embodiments of the invention are presented in the following claims.

1. A method of processing a substrate, the method comprising:
generating a mask density map based on a photomask, the mask density map spatially mapping transparent regions of the photomask and blocking regions of the photomask that block radiation at a predetermined wavelength;
generating a flare map based on the mask density map, the flare map spatially indicating a projected amount of received radiation in excess of a desired amount of radiation at each coordinate location on the photomask;
generating a critical dimension modification map based on the flare map, the critical dimension modification map including a modification energy dosage for each coordinate location on the photomask;
coating a first surface of the substrate with a photosensitive resist;
exposing the first surface of the substrate to a first pattern of radiation at the predetermined wavelength when the photomask is provided between the first surface of the substrate and a source of the radiation; and
exposing the first surface of the substrate to a second pattern of radiation at the predetermined wavelength, the second pattern being based on modification energy dosages of the critical dimension modification map.

2. The method of claim 1, further comprising removing portions of the photosensitive resist after exposing the first surface of the substrate to the first pattern of radiation and exposing the first surface of the substrate to the second pattern of radiation.

3. The method of claim 2, wherein removing portions of the photosensitive resist includes removing portions that are soluble in a liquid developer.

4. The method of claim 2, wherein removing portions of the photosensitive resist includes a plasma-based removal process.

5. The method of claim 1, wherein exposing the first surface of the substrate to the first pattern of radiation is performed prior to the exposing the first surface of the substrate to the second pattern of radiation.

6. The method of claim 1, wherein exposing the first surface of the substrate to the second pattern of radiation is performed prior to exposing the first surface of the substrate to the first pattern of radiation.

7. The method of claim 1, wherein a maximum radiation energy of the second pattern of radiation is less than 10% of a maximum radiation energy of radiation in the first pattern of radiation.

8. The method of claim 1, wherein a radiation energy of the second pattern of radiation is approximately 0.1% to 5% of a radiation energy of the first pattern of radiation.

9. The method of claim 1, wherein the mask density map is a grid-based map.

10. The method of claim 1, wherein the photomask is a composite of more than one photomask and the first pattern of radiation is repeated for each photomask of the composite.

11. The method of claim 1, wherein the second pattern of radiation is delivered by direct write lithography.

12. The method of claim 1, wherein a maximum radiation energy of the first pattern of radiation is less than the desired amount of radiation.

13. A method of processing a substrate, the method comprising:
generating a mask density map based on a photomask, the mask density map spatially mapping transparent regions of the photomask and blocking regions of the photomask that block radiation at a predetermined wavelength;
generating a flare map based on the mask density map, the flare map spatially indicating a projected amount of electromagnetic radiation in excess of a desired amount of electromagnetic radiation received at each coordinate location on the photomask;
generating a critical dimension modification map based on the flare map, the critical dimension modification map including a modification energy dosage for each coordinate location on the photomask;
coating a first surface of the substrate with a photosensitive resist;
exposing the first surface of the substrate to a first pattern of radiation at the predetermined wavelength when the photomask is provided between the first surface of the substrate and a source of the radiation;
exposing the first surface of the substrate to a second pattern of radiation at the predetermined wavelength, the second pattern being based on modification energy dosages of the critical dimension modification map; and
removing portions of the photosensitive resist after exposing the first surface of the substrate to the first pattern of radiation and exposing the first surface of the substrate to the second pattern of radiation.

14. The method of claim 13, wherein exposing the first surface of the substrate to the first pattern of radiation is performed prior to the exposing the first surface of the substrate to the second pattern of radiation.

15. The method of claim 13, wherein exposing the first surface of the substrate to the second pattern of radiation is performed prior to exposing the first surface of the substrate to the first pattern of radiation.

16. The method of claim 13, wherein a maximum radiation energy of the second pattern of radiation is less than 10% of a maximum radiation energy of radiation in the first pattern of radiation.

17. The method of claim 13, wherein a radiation energy of the second pattern of radiation is approximately 0.1% to 5% of a radiation energy of the first pattern of radiation.

18. The method of claim 13, wherein the mask density map is a grid-based map.

19. The method of claim 13, wherein the photomask is a composite of more than one photomask and the first pattern of radiation is repeated for each photomask of the composite.

20. The method of claim 13, wherein the second pattern of radiation is delivered by direct write lithography.
